(19) United States
(12) Patent Application Publication
(10) Pub. No.: US 2023/0238969 A1
(43) Pub. Date: Jul. 27, 2023

(54) SAMPLING SIGNALS

(71) Applicant: Nordic Semiconductor ASA, Trondheim (NO)

(72) Inventor: Kyrre Gonsholt, Trondheim (NO)

(73) Assignee: Nordic Semiconductor ASA, Trondheim (NO)

(21) Appl. No.: 18/099,859

(22) Filed: Jan. 20, 2023

(30) Foreign Application Priority Data
Jan. 25, 2022 (GB) 2200930.2

(51) Int. Cl. H03L 7/14; H03L 7/085; H03K 19/21

(52) U.S. Cl. CPC H03L 7/14; H03K 19/21; H03L 7/085

(57) ABSTRACT

An asynchronous circuit portion for sampling an input signal is provided. The circuit portion comprises a sampling circuit portion arranged to sample the input signal to generate a sanitized output signal corresponding to the input signal; a comparison circuit portion arranged to compare the sanitized output signal with the input signal and to generate a change signal if the sanitized output signal does not correspond to the input signal; and a control circuit portion arranged to trigger the sampling circuit portion to sample the input signal to generate an updated sanitized output signal, in response to the change signal.

### CROSS REFERENCE TO RELATED APPLICATION

This application claims priority to Great Britain Application No. 2200930.2, filed Jan. 25, 2022, which application is incorporated herein by reference in its entirety.

### FIELD

The present invention relates to sampling signals, e.g. as part of asynchronous logic.

### BACKGROUND

Asynchronous logic (i.e. logic that does not operate according to a repeating clock signal) can be used to improve the speed of digital devices, as data processing can happen as fast as the logic allows, without being limited by the speed of a clock signal. Furthermore, because the logic does not require a clock signal to be generated or balanced its power consumption and area may be reduced.

However, because their operation is not coordinated by a common clock signal, circuits utilising asynchronous logic may be more susceptible to glitches causing errors such as metastability and race conditions. One source of glitches may be external inputs to a circuit (e.g. transient changes in an input signal that do not correspond to intended input data). It is therefore advantageous to be able to generate a sanitized glitch-free (or at least glitch-reduced) signal from a glitchy input signal.

### SUMMARY

Various approaches have been proposed for sampling potentially glitchy input signals to produce sanitized signals. However, often these approaches are relatively slow, causing undesirable delays between a circuit requesting a new sample of an input signal and actually receiving the sanitized version. An improved approach may be desired.

According to a first aspect of the present invention there is provided an asynchronous circuit portion for sampling an input signal comprising:
a sampling circuit portion arranged to sample the input signal to generate a sanitized output signal corresponding to the input signal;
a comparison circuit portion arranged to compare the sanitized output signal with the input signal and to generate a change signal if the sanitized output signal does not correspond to the input signal;
a control circuit portion arranged to trigger the sampling circuit portion to sample the input signal to generate an updated sanitized output signal, in response to the change signal.

According to a second aspect of the present invention there is provided a method of asynchronously sampling an input signal comprising:
sampling the input signal at a first time to generate a sanitized output signal corresponding to the input signal at the first time:
comparing the sanitized output signal with the input signal at a second time; and
if the sanitized output signal does not correspond to the input signal at the second time, sampling the input signal again to generate an updated sanitized output signal.

Thus, it will be seen by those skilled in the art that asynchronous circuit portions in accordance with the present invention are able to provide a sanitized output signal that more reliably corresponds to the present input signal, because the output signal is updated in response to a comparison of the input and output signals, rather than, for example, only in response to an external request for a new sample, thereby reducing delays.

In some embodiments the comparison circuit portion is arranged to compare continuously the input and output signals, such that a change signal is generated every time the output signal is different to the input signal (i.e. whenever the input signal changes from a previously sampled state). The control circuit portion may be arranged to trigger the sampling circuit portion to sample the input signal to generate an updated sanitized output signal every time a change signal is generated. This may ensure that the sanitized output signal is kept continuously up-to-date with changes to the input signal. An external circuit receiving the output signal may thus be updated more promptly on all changes to the input signal.

It will be appreciated that the sanitized output signal comprises a glitch-free or glitch-reduced version of the input signal. The sanitized output signal is preferably substantially free of glitches, noise or other transient changes in state, to avoid issues in downstream asynchronous circuitry in which transient glitches could cause errors and/or delays.

The input signal may comprise a digital signal that can assume one of a limited number of states (e.g. a low state and a high state). The two states may be defined by predetermined voltage values or ranges. In some embodiments, the input signal may be considered to have a first state when it has a voltage below a predetermined threshold and a second state when it has a voltage above the predetermined threshold (or vice-versa). The first state may comprise a logic low (e.g. a lower voltage), and the second state may comprise a logic high (e.g. a higher voltage). Of course, in other embodiments the first state comprises a logic high, and the second state comprises a logic low. The output signal may simply have a state that matches the state of the sampled input signal. The sanitized output signal may comprise a version of the sampled input signal (e.g. an inverted, amplified and/or encoded version).

In some embodiments the comparison circuit portion is arranged to react to differences between the input and output signals that persist for at least a minimum detection time and/or have a magnitude above a minimum detection threshold. This may reduce the chances of the comparison circuit portion triggering a new sample in response to noise or transient glitches in the input signal, i.e. when the underlying “true” input signal has not changed. In some embodiments, the minimum detection time and/or the minimum detection threshold is selected based on the expected duration and/or magnitude of glitches in the input signal. Additionally or alternatively, the minimum detection time and/or the minimum detection threshold may arise at least partially as a result of inherent component properties of the comparison circuit portion. However, it will be recognised that it is not essential for the comparison circuit portion to avoid triggering a new sample in response to glitches in the input signal, as any such glitches may subsequently be filtered out by the sampling circuit portion e.g. as set out below.

The sampling circuit portion is preferably arranged to avoid sampling the input signal during a glitch or transient change, such that the sanitized output signal corresponds accurately to the “true” input signal at the time of sampling. In other words, the sampling circuit portion is preferably arranged to filter out glitches in the input signal.

In some embodiments, the sampling circuit portion is arranged to output a sanitized output signal that corresponds to a state of the input signal that has persisted for a minimum duration after a sampling time. For instance, the sampling circuit portion may be arranged to output a sanitized output signal corresponding to a first state if the input signal is in the first state for a first minimum duration after a sample is triggered and/or to generate a sanitized output signal corresponding to a second state if the input signal has a second state for a second minimum duration after a sample is triggered. The first and second minimum durations may be the same but this is not essential. Requiring the input signal to maintain the first or second state for a minimum duration before may reduce the chances of the sampling circuit portion inadvertently sampling the state of input signal during a transient glitch. The minimum duration(s) may be selected based on (e.g. greater than) a maximum expected length of glitch. In some embodiments the minimum duration(s) may be based on internal delays in the sampling circuit portion

The sampling circuit portion may comprise any suitable circuit portion capable of sampling a glitchy input signal to generate a sanitized output signal. In some embodiments, the sampling circuit portion may comprise one or more sampling elements (e.g. storage elements such as latches) configured to detect one or more respective states of an input signal. The one or more sampling elements may be configured to detect a state of the input signal only if the input signal maintains that state for a minimum duration. The sampling circuit portion may comprise arbitration logic configured to produce a single sanitized output signal corresponding to the input signal. In a set of embodiments, the sampling circuit portion comprises a first sampling element configured to generate a first sample signal if the input signal has a first state, a second sampling element configured to generate a second sample signal if the input signal has a second state, and arbitration logic arranged to detect an earliest sample signal from the first and second sample signals and to generate the sanitized output signal corresponding to the earliest sample signal.

In some embodiments, the control portion is arranged to trigger a new sample by issuing a start command to the sampling circuit portion. As explained above, circuit portions in accordance with the present invention are able to generate automatically an up-to-date sanitized output signal. However, at some times it may not be necessary for the output signal to be continually updated with every change of the input signal. For instance, an external circuit may not be able to react or process updates to the sanitized output signal at certain times (e.g. whilst it is processing a response to a previous update of the output signal). In some such situations continuously updating the output signal may be inefficient. Therefore, in some embodiments the circuit portion is operable in a hold mode in which the sanitized output signal is held constant, regardless of changes to the input signal. In other words, in the hold mode the sanitized output signal is not updated. This may allow the circuit portion to save power by only updating the sanitized output signal when necessary.

The comparison circuit portion may be arranged to switch off in the hold mode, so that changes to the input signal are simply not detected and change signals are not generated. However, in some embodiments the control circuit portion is arranged to ignore change signals in the hold mode, so that new samples are not triggered in the hold mode. In some such embodiments, the comparison circuit portion may remain operational in the hold mode. The control circuit portion may thus be able to react more quickly when the period of hold mode operation ends because a change signal generated during the hold mode may immediately trigger a new sample, causing an up-to-date sanitized output signal to be generated promptly at the end of hold mode operation. It will be appreciated that, if the sanitized output signal does not change during a period of hold mode operation, the asynchronous circuit portion can provide an up-to-date sample immediately at the end of hold mode operation. This represents a significant improvement over previous approaches in which a new sample must always be taken for the circuit to be confident that a sanitized output signal corresponds to a potentially glitchy input signal.

When the circuit portion is powered and operational but not in the hold mode, it may be considered to be operating in an active mode. In other words, the circuit portion may be arranged to operate in an active mode in which the control circuit portion is arranged to trigger the sampling circuit portion to sample the input signal to generate the updated sanitized output signal, in response to the change signal, when not in the hold mode. The active mode may comprise a default mode in which the circuit portion operates whenever the hold mode is not activated.

The circuit portion may be arranged to enter the hold mode in response to receiving a hold request signal (e.g. from an external circuit). The circuit portion may be arranged to issue a hold acknowledge signal in response to the hold request signal, e.g., to confirm that a hold request signal has been received and/or to confirm that it is or will imminently be operating in the hold mode. The hold request signal and hold acknowledge signals may form part of a handshake protocol between the circuit portion and an external circuit portion. The de-assertion of a hold request signal from an external circuit may be considered analogous to the external circuit requesting a new sample of the input signal. However, as explained above, in at least some situations (i.e. where the input signal and output signal already correspond when the hold mode ends) an up-to-date sanitized output signal is effectively immediately available at the end of hold mode operation, without needing to wait for a new sample to be taken.

In a set of embodiments, the circuit portion comprises a mutual-exclusion (MUTEX) element configured to take the hold request signal as a first input and the change signal as a second input. This may be a particularly quick and simple way testing if the input signal has changed during hold mode. A MUTEX element (also referred to as an arbiter) only allows one input through at a time. In such embodiments, the MUTEX element will not allow the change signal through whilst the hold request signal is asserted (i.e. in the hold mode). When the hold request signal is lowered (at the end of the hold mode) the MUTEX may provide an immediate indication of whether the input signal has changed during the hold mode operation. This may enable faster performance.

The comparison circuit portion may comprise a comparator such as an Exclusive-OR (XOR) logic gate, e.g., an XOR logic gate arranged to receive the input signal and the output signal as inputs and to generate the change signal as an output. The change signal may be sent directly to the control circuit portion. However, in some embodiments the comparison circuit portion is arranged to send the change signal to the control circuit portion only when a change signal request signal is asserted. The control circuit portion may be arranged to assert the change signal request signal. The change signal request signal may be asserted when the control circuit portion is ready to react to a change signal (e.g. when the control circuit portion has finished processing a previous change signal). The asserting of the change signal request signal and the change signal may form part of a handshake protocol between the control circuit portion and the comparison circuit portion. In some embodiments, additionally or alternatively, the change signal request signal may be used to implement hold mode functionality. For instance, the change signal request signal may only be asserted when the circuit portion is in the active mode, i.e. the change signal request signal may not be asserted when the circuit portion is in the hold mode.

In some embodiments, the circuit portion is arranged to output a ready signal when the sanitized output signal corresponds to the input signal, i.e. to indicate when the sanitized output signal is up-to-date and available for use. This may aid operation of external circuits that utilise the sanitized output signal. The circuit portion may be arranged to output the ready signal whenever the change signal is not generated by the comparison circuit portion.

It will be understood that the various signals described herein may be implemented by raising or lowering a voltage on an electrical conductor. For instance, one or more of the signals described herein may comprise the assertion of a digital high or a digital low on a connection between two components. However, it will be appreciated by those skilled in the art that any suitable electrical signal may be utilised to effect the signals including changes in analogue voltage levels or encoded data packets.

Features of any aspect or embodiment described herein may, wherever appropriate, be applied to any other aspect or embodiment described herein. Where reference is made to different embodiments, it should be understood that these are not necessarily distinct but may overlap.

### BRIEF DESCRIPTION OF DRAWINGS

One or more non-limiting examples will now be described, by way of example only, and with reference to the accompanying figures in which:

FIG. 1 is a schematic diagram of a circuit portion according to an embodiment of the invention;

FIG. 2 is a schematic diagram of the control circuit portion shown in FIG. 1;

FIGS. 3 and 4 are timing diagrams illustrating active mode operation of the circuit portion of FIG. 1;

FIG. 5 is a timing diagram illustrating hold mode operation of the circuit portion of FIG. 1; and

FIG. 6 is a schematic diagram of the sampling circuit portion shown in FIG. 1.

### DETAILED DESCRIPTION

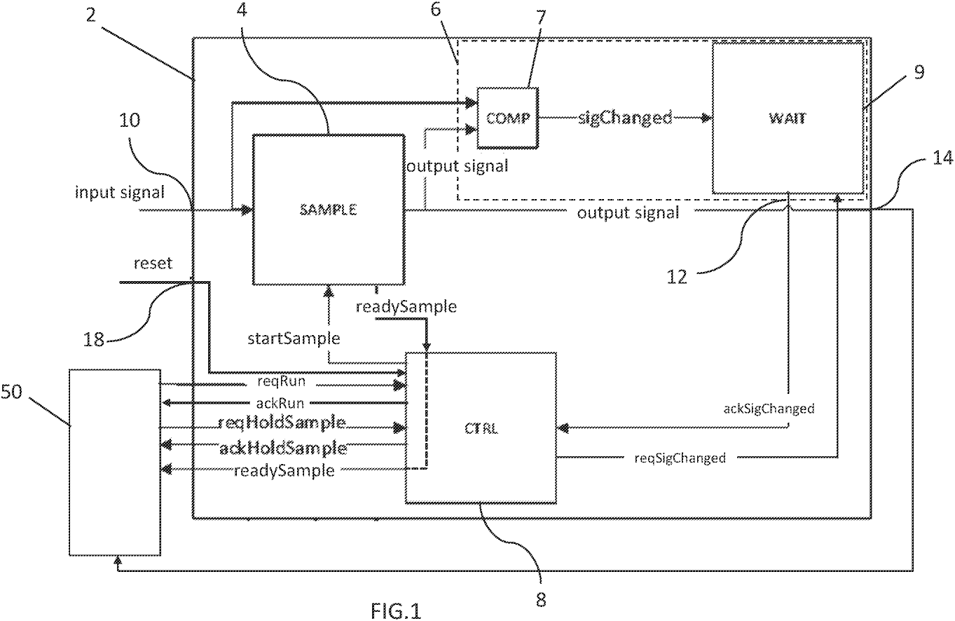

FIG. 1 shows a circuit portion 2 comprising a sampling circuit portion 4, a comparison circuit portion 6 and a control circuit portion 8. The circuit portion \2 comprises an input 10 at which a potentially-glitchy input signal is received, and a sanitized output 14 from which a sanitized output signal is provided. The output \14 is connected to an external circuit 50. The circuit portion 2 also comprises a reset input 18.

The comparison circuit portion 6 comprises a comparator 7 (e.g. an XOR logic gate) and a handshake portion 9. The comparator 7 takes the input 10 and sanitized output 14 as inputs and sends an output sigChanged to the handshake portion 9. The handshake portion 9 of the comparison circuit portion 6 outputs a change signal ackSigChanged from a change output 12 if the input 10 and the sanitized output 14 are different (i.e. if the input signal and the sanitized output signals are different), and a change signal request signal reqSigChanged is asserted.

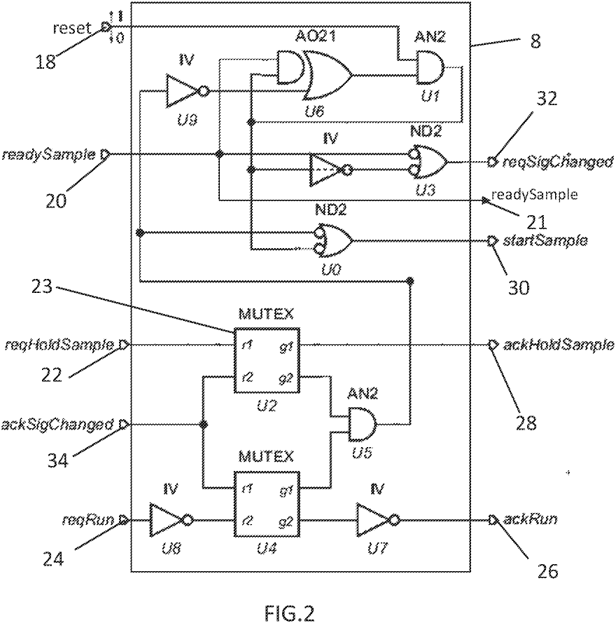

The control circuit portion 8 is shown in more detail in FIG. 2. The control circuit portion 8 receives and issues various control signals within the circuit portion 2 and externally (e.g. to and from the external circuit 50). The external connections of the control circuit portion 8 comprise the reset input 18, a sample ready output 21, a hold request input 22, a run request input 24, a run acknowledge output 26 and a hold acknowledge output 28. The internal connections of the control circuit portion 8 comprise a sample ready input 20, a sample trigger output 30, a signal change request output 32 and a signal change acknowledge input 34. In this embodiment the control circuit portion 8 passes signals received from the sample ready input 20 to the sample ready output 21. In other embodiments the sampling circuit portion 4 may provide a sample ready connection directly to the external circuit 50.

The circuit portion 8 also comprises a MUTEX element 23 that has the hold request input 22 as a first input r1 and the signal change acknowledge input 34 as a second input r2 (see FIG. 2). The first output g1 of the MUTEX element 23 provides the hold acknowledge output 28 and the second output g2 of the MUTEX element 23 is connected to circuitry leading to the signal change request output 32, the sample ready output 21 and the sample trigger output 30. The MUTEX is configured to assert a signal on only one output g1, g2 at a time, according to which input r1, r2 receives an asserted signal first.

The circuit portion 2 is switched on by receiving a run request signal reqRun on the run request input 24, on receipt of which the control circuit portion 8 asserts a run acknowledge signal ackRun on run acknowledge output 26. The circuit portion 2 is operable in an active mode and a hold mode under the control of the external circuit 50. When the control circuit portion 8 receives a hold request signal reqHoldSample at the hold request input 22 it enters the circuit portion 2 into the hold mode and asserts an acknowledgement signal ackHoldSample on the hold acknowledge output 28. When the hold request signal reqHoldSample is lowered by the external circuit 50 the control circuit portion 8 enters the circuit portion 2 into the active mode and lowers the acknowledgement ackHoldSample. It will be appreciated that the run request signal and/or run acknowledge signal are not essential. For instance, in some embodiments the circuit portion 2 is simply always on when it is powered. The circuit portion 2 may operate in the active mode as a default mode and operate in the hold mode when a hold request signal is received.

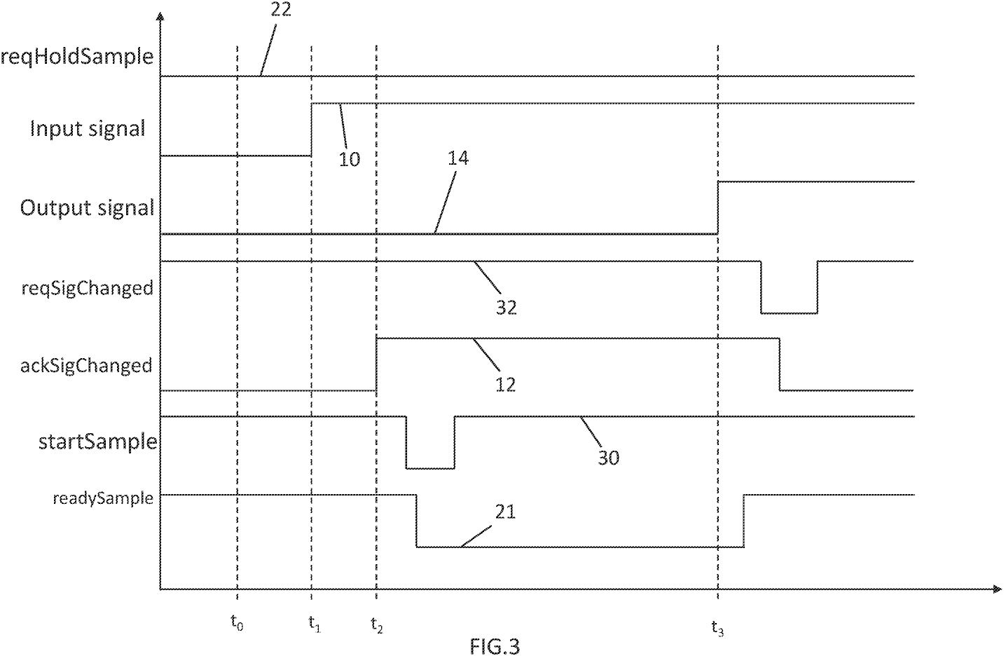

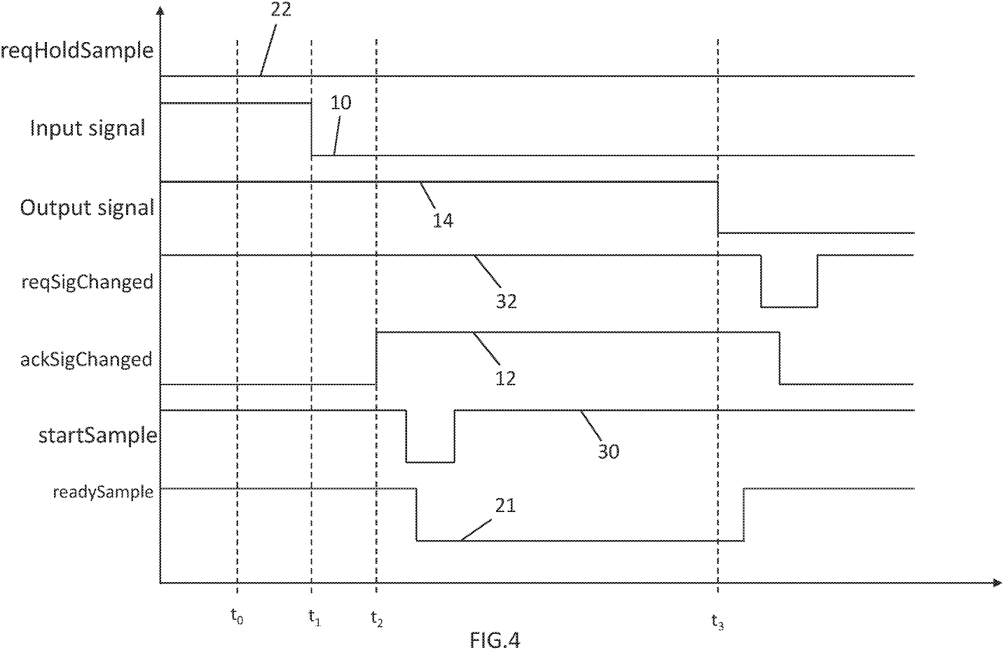

The active mode of operation will be described first, with additional reference to the timing diagrams shown in FIGS. 3 and 4. As will be explained in more detail, in the active mode the circuit portion 2 continuously compares the input 10 and the sanitized output 14 and the control circuit portion 8 triggers the sampling circuit 4 portion to take a new sample of the input 10 whenever the input signal differs from the sanitized output signal (i.e. whenever the input changes). This keeps the sanitized output signal continuously up-to-date.

Referring now to the operation illustrated in the timing diagram of FIG. 3, at a first time t₀ the run request input 24 is high, the hold request input 22 is low and so the circuit portion 2 is in the active mode. The input signal at the input 10 is low and the sanitized output 14 is also low (i.e. from a previous sampling of the input 10). Because the input signal and the sanitized output signal are the same, the comparison circuit portion 6 does not assert the change signal at the change output 12. The reqSigChanged signal is being asserted on the signal change request output 32 by the control circuit portion 8. The reqSigChanged signal indicates that the control circuit 8 is ready to react to changes in state of the input signal.

At a time t₁, the input 10 goes high. The input and output signals are now different and at t₂, after a short delay for the logic in the comparison circuit portion 6 to react, the change signal ackSigChanged is asserted by the comparison circuit portion 6 at change output 12. The short delay in the comparison circuit portion 6 helps to avoid transient changes in the input signal triggering the change signal ackSigChanged.

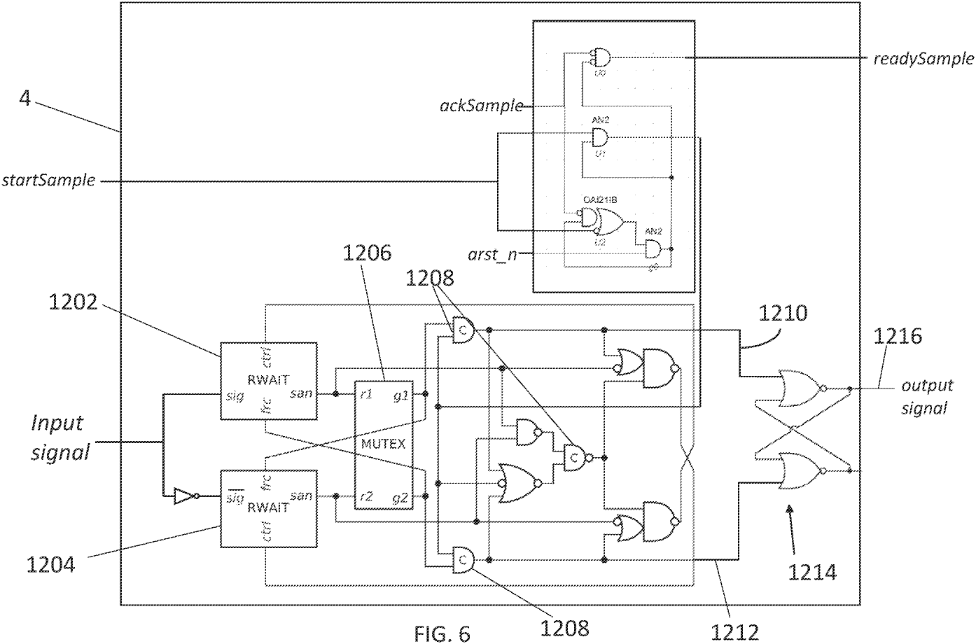

In response to the change signal ackSigChanged, the control circuit portion 8 triggers the sampling circuit portion 4 to sample the input 10 and thus update the sanitized output signal by briefly lowering the startSample signal. The sampling circuit portion 4 lowers the readySample signal input to the sample ready input 20 and begins the sampling process. The operation of the sampling circuit portion 4 is described in more detail below with reference to FIG. 6. The lowered readySample signal is output from the sample ready output 21 and indicates to the external circuit that the current sanitized output 14 is different to the current input 10, i.e. that the current sanitized output signal is not up-to-date.

At t₃, the sampling circuit portion 4 has completed the sampling process and the sanitized output 14 goes high to match the sampled input 10. The control circuit portion 8 then re-asserts the ready signal to indicate to the external circuit portion 50 that the output signal is once again up-to-date. Because the input 10 and the sanitized output 14 are now in correspondence, the control circuit portion 8 lowers the reqSigChanged signal, and the comparison circuit portion 6 consequently lowers the change signal ackSigChanged on the change output 12. The control circuit portion 8 then re-asserts the reqSigChanged signal to wait for the next change of the input signal.

FIG. 4 illustrates a corresponding set of operations for the situation in which the input 10 changes from high to low at time t₀ and the sanitized output 14 accordingly goes low at t₃. The operation of the circuit portion 2 is otherwise the same as that described with reference to FIG. 3.

FIGS. 3 and 4 illustrate how, in the active mode, the circuit portion 2 provides a continuously updated sanitized output signal to the external circuit 50. The external circuit 50 does not need to specifically request updates but is instead simply provided with these automatically.

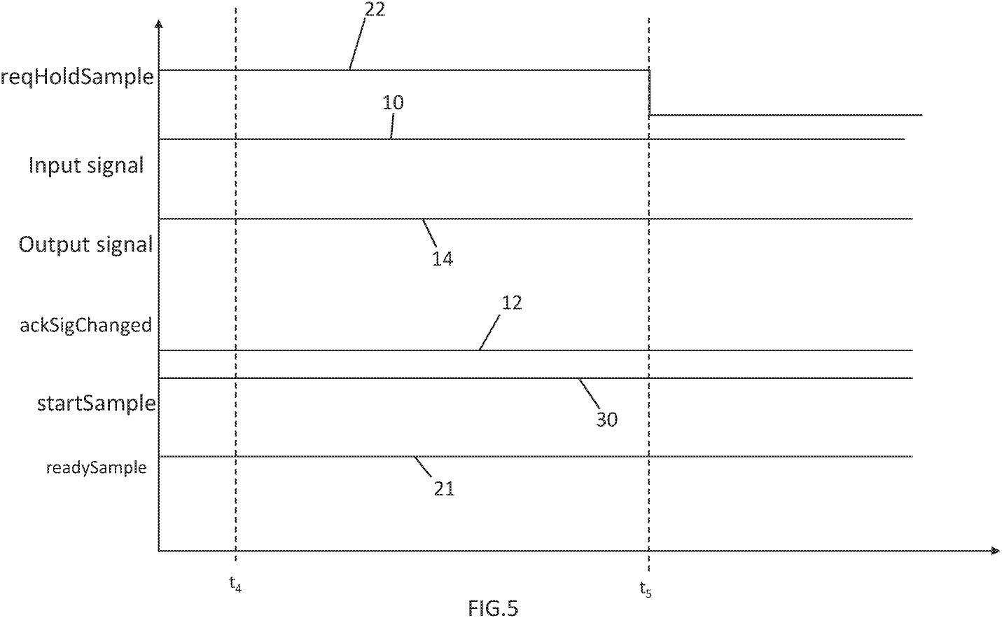

Hold mode operation of the circuit portion 2 will now be described with reference to the timing diagram in FIG. 5. The hold mode may be of use for periods of time when the external circuit 50 is not able to (or simply does not need to) react to changes to the sanitized output 14.

At t₄, the external circuit 50 is asserting a hold request signal reqHoldSample, which is received at the hold request input 22 of the control circuit portion 8. In response, the control circuit portion 8 puts the circuit portion 2 into the hold mode and outputs a hold acknowledge signal ackHoldSample from the hold acknowledge output 28. At t₄, the input 10 and the sanitized output 14 are both high.

At t₅, the external circuit 50 lowers the hold request signal reqHoldSample. The input signal 10 has not changed during the hold mode (e.g. because it comes from a stable source), and so the change signal ackSigChanged is low at the change signal output 12.

The sanitized output signal is thus already in correspondence with the input signal and no new sample needs to be taken. Both inputs to the MUTEX element 23 are now low and it immediately indicates that no new sample needs to be taken by not asserting a signal on either of its outputs. The external circuit 50 is thus provided with an up-to-date sample of the input 10 as soon as the hold request acknowledge signal is lowered (i.e. very shortly after ts). This represents a significant speed increase over prior art approaches that require a new sample to be taken to be confident that the input signal corresponds to the output signal. For instance, in one simulation of the circuit portion 4 the control circuit portion 8 took an average of 0.208 ns to lower the hold request acknowledge signal in response to the lowering of the hold request signal, but took an average of 1.745 ns to take a new sample of the input signal with the sampling circuit portion 6. Thus in at least some situations the invention may be approximately eight times faster than previous approaches. The sampling circuit portion 6 is shown in more detail in FIG. 6. The sample circuit portion 6 comprises two sampling elements 1202, 1204 that are used to detect the state of the input signal sig on receipt of the start signal startSample. The first sampling element 1202 outputs a logic high signal when the input signal goes low, and the second sampling element 1204 outputs a logic high signal when the input signal goes high. The outputs of these sampling elements 1202, 1204 feed into additional logic including a mutual exclusion element 1206 and several Muller-C elements 1208, which are arranged to produce a first stable output 1210 that is logic high when the sampled signal is logic low and a second stable output 1212 that is logic high when the sampled signal is logic high.

The sampling circuit portion 6 further comprises an RS latch 1214 that receives the first stable output 1210 and the second stable output 1212 and produces the sanitised output signal at output 1216.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

I claim:

1. An asynchronous circuit portion for sampling an input signal comprising:
a sampling circuit portion arranged to sample the input signal to generate a sanitized output signal corresponding to the input signal;
a comparison circuit portion arranged to compare the sanitized output signal with the input signal and to generate a change signal if the sanitized output signal does not correspond to the input signal; and
a control circuit portion arranged to trigger the sampling circuit portion to sample the input signal to generate an updated sanitized output signal, in response to the change signal.

2. The asynchronous circuit portion of claim 1, wherein the control circuit portion is arranged to trigger the sampling circuit portion to sample the input signal to generate an updated sanitized output signal every time a change signal is generated.

3. The asynchronous circuit portion of claim 1, wherein the sampling circuit portion comprises a first sampling element configured to generate a first sample signal if the input signal has a first state, a second sampling element configured to generate a second sample signal if the input signal has a second state, and arbitration logic arranged to detect an earliest sample signal from the first and second sample signals and to generate the sanitized output signal corresponding to the earliest sample signal.

4. The asynchronous circuit portion of claim 1, wherein the control portion is arranged to trigger a new sample by issuing a start command to the sampling circuit portion.

5. The asynchronous circuit portion of claim 1, wherein the circuit portion is operable in a hold mode in which the sanitized output signal is held constant, regardless of changes to the input signal.

6. The asynchronous circuit portion of claim 5, wherein the control circuit portion is arranged to ignore change signals in the hold mode.

7. The asynchronous circuit portion of claim 5, arranged to enter the hold mode in response to receiving a hold request signal.

8. The asynchronous circuit portion of claim 7, comprising a mutual-exclusion element arranged to take the hold request signal as a first input and the change signal as a second input.

9. The asynchronous circuit portion of claim 1, wherein the comparison circuit portion comprises an Exclusive-OR logic gate.

10. The asynchronous circuit portion of claim 1 wherein the comparison circuit portion is arranged to send the change signal to the control circuit portion only when a change signal request signal is asserted.

11. The asynchronous circuit portion of claim 1, arranged to output a ready signal when the sanitized output signal corresponds to the input signal.

12. A method of asynchronously sampling an input signal comprising:
sampling the input signal at a first time to generate a sanitized output signal corresponding to the input signal at the first time:
comparing the sanitized output signal with the input signal at a second time; and
if the sanitized output signal does not correspond to the input signal at the second time, sampling the input signal again to generate an updated sanitized output signal.
